(19) United States
(12) Patent Application Publication
(10) Pub. No.: US 2026/0062809 A1
(43) Pub. Date: Mar. 5, 2026

(54) FLEXIBLE ELEMENT FOR A SUBSTRATE PROCESSING CHAMBER

(71) Applicant: Applied Materials, Inc., Santa Clara, CA (US)

(72) Inventors: Upendra UMMETHALA, Santa Clara, CA (US); Kaushik ALAYAVALLI, Sunnyvale, CA (US); Samir NAYFEH, Santa Clara, CA (US); Tuan Anh NGUYEN, San Jose, CA (US); Vishwas BASAVARAJAIAH SOMASHEKAR, Bangalore (IN); Amit HATTANGADI, Karnataka (IN); Hari Prasath RAJENDRAN, Bangalore (IN); Chethan SOMANAHALLI MALLESHAPPA, Bengaluru (IN)

(21) Appl. No.: 19/302,214

(22) Filed: Aug. 18, 2025

(30) Foreign Application Priority Data
Aug. 28, 2024 (IN) 202441064999

(51) Int. Cl. C23C 16/458

(52) U.S. Cl. CPC C23C 16/4585

(57) ABSTRACT

A flexible element is configured to form a seal between a seal plate and another component in a substrate processing chamber. The flexible element includes a first portion engaged with a first interface surface of the seal plate, and a second portion facing a second interface surface of the component in the processing chamber. An intermediate portion spans from the first portion to the second portion. The intermediate portion is configured to flex to accommodate a misalignment between the first interface surface and the second interface surface by allowing relative movement between the first and second portions.

### CROSS-REFERENCE TO RELATED APPLICATIONS

This application claims benefit of Indian Provisional application No. 202441064999, filed Aug. 28, 2024, which is incorporated herein by reference in its entirety.

### BACKGROUND

### Field

Embodiments of the present disclosure generally relate to a substrate support design for a substrate processing chamber, such as is used in semiconductor processing or the like.

### Description of the Related Art

Substrate processing chambers, such as those used in semiconductor processing or the like, typically have a substrate support that can be moved vertically between a lowered position and a raised position. The substrate support is moved to the lowered position to facilitate the transfer of a substrate into, and out of, the processing chamber. The substrate support is moved to the raised position to facilitate the processing of a substrate disposed thereon. In some processing chambers, the substrate support includes a support plate and a seal plate that are used to isolate a processing region of the processing chamber from the rest of the processing chamber during processing. The support plate includes a support surface on which a substrate is disposed during processing. The seal plate is configured to form a seal with another chamber component, such as a liner assembly, when the substrate support is in the raised position.

In some processing chambers, when the substrate support is in a raised position (e.g., processing position), the substrate and a showerhead of the processing chamber can be misaligned. For example, the substrate might not be parallel with the showerhead because the support surface of the substrate support is not parallel with the showerhead. Such misalignment can result in uneven processing of the substrate, which adversely affects product quality and yield.

In some processing chambers, when the substrate support is in the raised position, the seal between the seal plate and a chamber component can be compromised by misalignment of the seal plate with respect to the chamber component. The compromised seal can result in processing gases escaping from the processing region and the deposition of contaminants in various regions of the processing chamber.

There is a need for improved systems that address the problems described above.

### SUMMARY

The present disclosure generally relates to a flexible element to facilitate formation of a seal despite a misalignment of a seal plate relative to another component. In one aspect, an assembly for use in a substrate processing chamber includes a flexible element. The flexible element includes a first portion that is annular, a second portion circumscribing the first portion, and an intermediate portion spanning between the first portion and the second portion. The intermediate portion is impermeable, and is configured to flex to allow adjustment of a position of the first portion relative to the second portion.

In another aspect, a processing chamber includes a chamber body. A seal plate is disposed in the chamber body, and includes a first interface surface. A second interface surface is disposed in the chamber body. The processing chamber further includes a flexible element that includes a first portion engaged with the first interface surface, a second portion facing the second interface surface, and an intermediate portion spanning between the first portion and the second portion. The intermediate portion is impermeable, and is configured to flex to allow adjustment of a position of the first portion relative to the second portion.

In another aspect, a processing chamber includes a chamber body. A seal plate is disposed in the chamber body, and includes a first interface surface. A second interface surface is disposed in the chamber body. The processing chamber further includes a flexible element that includes a first portion engaged with the second interface surface, a second portion facing the first interface surface, and an intermediate portion spanning between the first portion and the second portion. The intermediate portion is impermeable, and is configured to flex to allow adjustment of a position of the first portion relative to the second portion.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1A is a schematic view of a processing chamber in which a substrate support is in a lowered position, according to one or more embodiments disclosed herein.

FIG. 1B is a schematic view of the processing chamber of FIG. 1A in which the substrate support is in a raised position for the processing of a substrate, according to one or more embodiments disclosed herein.

FIG. 2 illustrates a schematic cross-sectional view of a processing chamber, according to one or more embodiments disclosed herein.

FIG. 3 illustrates a schematic cross-sectional view of a processing chamber, according to one or more embodiments disclosed herein.

FIG. 4 illustrates a schematic cross-sectional view of a processing chamber, according to one or more embodiments disclosed herein.

FIG. 5 illustrates a schematic cross-sectional view of a processing chamber, according to one or more embodiments disclosed herein.

FIG. 6 illustrates a schematic cross-sectional view of a processing chamber, according to one or more embodiments disclosed herein.

FIG. 7 illustrates a schematic cross-sectional view of a flexible assembly at a base of a processing chamber, according to one or more embodiments disclosed herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a substrate support assembly design used in a substrate processing chamber that includes one or more flexible elements that are configured to contact one or more substrate processing chamber components to isolate a first region of the processing chamber from a second region of the processing chamber during the processing of a substrate. In some embodiments, the flexible element facilitates the maintaining a seal between a seal plate of a substrate support and another chamber component, such as a liner assembly, despite the seal plate being misaligned with the chamber component. In some embodiments, the flexible element is disposed within the processing chamber and further between and engaged with the seal plate and the chamber component. In some embodiments, a plurality of flexible elements are exterior to the processing chamber and are used to couple the seal plate to the support plate such that the seal plate can move independently of the substrate support to facilitate aligning the seal plate with the other component to facilitate forming a seal.

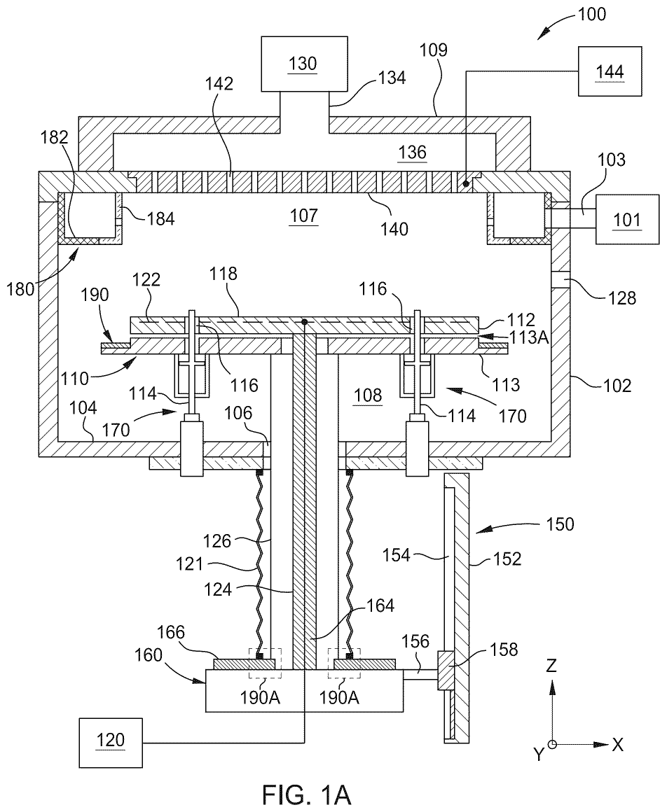

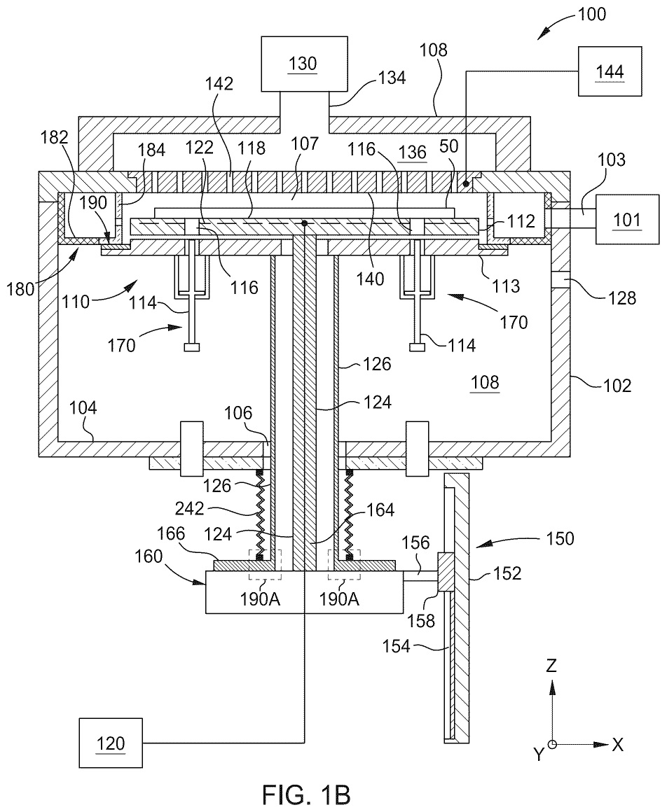

FIGS. 1A and 1B are schematic cross-sectional views of a processing chamber 100. In general, the processing chamber 100 can include an atomic layer deposition (ALD) chamber, chemical vapor deposition (CVD) chamber, physical vapor deposition (PVD) chamber, etch chamber, degas chamber, an ion implantation chamber, ashing chamber, cleaning chamber, a thermal processing chamber (e.g., rapid thermal processing, anneal, cool down, thermal management control), or other type of substrate processing chamber.

However, as illustrated in FIGS. 1A and 1B, the processing chamber 100 is configured as a Plasma Enhanced Chemical Vapor Deposition (“PECVD”) chamber. Nevertheless, the processing chamber 100 may be configured to perform one or more other processing operations that may or may not involve a plasma. The processing chamber 100 may include relevant hardware associated with any of the above processes.

The processing chamber 100 includes a chamber body 102 with a floor 104, a substrate support 110 disposed inside the chamber body 102, and a lid 109 coupled to the chamber body 102. FIG. 1A shows the substrate support 110 in a lowered position, such as when a substrate is transferred into or out of the processing chamber 100. FIG. 1B shows the substrate support 110 in a raised position (e.g., processing position), such as when a substrate is being processed. In the raised position, a seal plate 113 of the substrate support 110 engages another component, such as a liner assembly 180, to form a first region 107 (e.g., processing region) where the substrate processing is performed. The first region 107 is isolated from a second region 108, which is the surrounding open volume of the interior of the chamber body 102, while the seal plate 113 is in the raised position. In some embodiments the processing chamber 100 includes a showerhead 140 that introduces gases into the first region 107. In some of such embodiments, the showerhead 140 can serve as an electrode, and is coupled to a power source 144 through a match circuit (not shown). The power source 144 is a radio frequency (RF) power source that is electrically coupled to the electrode. Further, the power source 144 provides between about 100 Watts and about 3,000 Watts at a frequency of about 50 kHz to about 15 MHz. In some embodiments, the power source 144 can be pulsed during various operations. The electrode and power source 144 facilitate control of a plasma formed within the first region 107.

The showerhead 140 features openings 142 for admitting a process gas or gases into the first region 107 from a gas supply source 130. The process gases are supplied to the processing chamber 100 via a gas feed 134, and the process gases enter a plenum 136 prior to flowing through the openings 142. In some embodiments, different process gases that are delivered simultaneously during a processing operation enter the processing chamber 100 via separate gas feeds and separate plenums prior to entering the first region 107 through the showerhead 140.

The gas supply source 130 includes one or more gas sources. The gas supply source 130 is configured to deliver the one or more gases from the one or more gas sources through the showerhead 140 and into the first region 107. Each of the one or more gas sources provides a process gas such as silane, disilane, tetraethyl orthosilicate (TEOS), germane, a metal halide (such as titanium tetrachloride, tantalum pentachloride, tungsten hexafluoride), an organometallic (such as tetrakis(dimethylamido) titanium, pentakis (dimethylamido) tantalum), ammonia, oxygen (O2), hydrogen peroxide, hydrogen (H2), diborane, chlorine (Cl2), sulfur hexafluoride, argon (Ar), helium (He), nitrogen (N2), and a hydrocarbon (generically CxHy), among others. In some embodiments, the process gas may be ionized to form a plasma within the first region 107. In an example, one or more of a carrier gas and an ionizable process gas are provided into the first region 107 to process a substrate 50 (FIG. 1B). For instance, when processing a 300 mm substrate, the process gases are introduced to the processing chamber 100 at a flow rate from about 6,500 sccm to about 8,000 sccm, from about 100 sccm to about 10,000 sccm, or from about 100 sccm to about 1000 sccm. Alternatively, other flow rates may be utilized. In some examples, a remote plasma source can be used to deliver plasma to the processing chamber 100 and can be coupled to the gas supply source 130.

In some embodiments, the processing chamber 100 includes a physical vapor deposition (PVD) target, which is similarly positioned as the showerhead 140 illustrated in FIGS. 1A and 1B, and thus takes the place of the showerhead 140. In such a configuration, the PVD target serves as a sputtering material source, and is coupled to the power source 144, which is typically a DC power source. The DC power source is adapted to provide a DC voltage at a power level that is typically greater than 1 kW. A magnetron (e.g., magnet assembly not shown) is positioned behind the PVD target and is used to help control the gas ion bombardment of the lower surface of the target during processing to allow for the uniform erosion (e.g., sputtering) of the target surface during processing.

In some embodiments, the processing chamber 100 includes a liner assembly 180. In some embodiments, the liner assembly 180 includes one or more liners 182. In some embodiments, the liner assembly 180 includes a pumping ring 184. Process gases flow into the first region 107 through the showerhead 140, then exit the first region 107 via the liner assembly 180. The process gases flow from the liner assembly 180 through an exhaust port 103 coupled to a vacuum pump 101. The vacuum pump 101 removes excess process gases or by-products from the first region 107 via the exhaust port 103 during and/or after processing the substrate 50.

The substrate 50 is provided to the first region 107 through an opening 128. In an example, the substrate 50 is transported into or out of the first region 107 using a carrier, such as a blade, that is conveyed by a robotic arm, such as a linear swapper.

The substrate support 110 includes a support plate 112 that includes a support surface 118 configured to support the substrate 50 in the first region 107 of the processing chamber 100 during processing. In some embodiments that may be combined with other embodiments, the support plate 112 is coupled to the seal plate 113. In some examples, a lower surface of the support plate 112 is coupled to an upper surface of the seal plate 113. As illustrated, in other examples, the lower surface of the support plate 112 and the upper surface of the seal plate 113 are separated by a gap 113A. In some embodiments that may be combined with other embodiments, the seal plate 113 is present, but is not coupled directly to the support plate 112. In some embodiments, the seal plate 113 may be omitted.

As illustrated, in some embodiments that may be combined with other embodiments, a flexible element 190 is disposed on a peripheral upward-facing surface (e.g., interface surface) of the seal plate 113. The flexible element 190 facilitates sealing the first region 107 from the second region 108 when the substrate support 110 is in the raised position (FIG. 1B) by engagement with another chamber component, such as the liner assembly 180. The sealing is achieved despite a misalignment between the seal plate 113 and the other component. In some embodiments, the flexible element 190 may be combined with one or more elastomeric seals.

In some embodiments, a gas bearing system may be used to maintain a small gap between the flexible element 190 and the other component (e.g., a portion of the liner assembly 180) to hinder particle generation at the flexible element 190 and to inhibit fluid communication between the first region 107 and the second region 108. In some examples, the small gap maintained by the gas bearing system is from about 0.01 mm to about 0.2 mm.

In some embodiments that may be combined with other embodiments, the flexible element 190 is disposed on a peripheral downward-facing surface of a chamber component, such as a component of the liner assembly, such as the liner 182 or the pumping ring 184. In at least some of such embodiments, the flexible element 190 is engaged by the seal plate 113 when the substrate support 110 is moved to the raised position depicted in FIG. 1B.

The support plate 112 contains, or is formed from, one or more metallic or ceramic materials. Exemplary metallic or ceramic materials include one or more metals, metal oxides, metal nitrides, metal oxynitrides, or any combination thereof. For example, the support plate 112 may contain or be formed from aluminum, aluminum oxide, aluminum nitride, aluminum oxynitride, boron nitride, or any combination thereof.

As illustrated, an electrode 122 is embedded within the support plate 112, but alternatively may be coupled to a surface (such as support surface 118) of the support plate 112. The electrode 122 is coupled to a power source 120. It is contemplated that the power source 120 may supply DC power, pulsed DC power, radio frequency (RF) power, pulsed RF power, or any combination thereof. The power source 120 is configured to drive the electrode 122 with a drive signal to generate a plasma within the first region 107. It is contemplated that the drive signal may be one of a DC signal and a varying voltage signal (e.g., RF signal). Further, the electrode 122 may alternatively be coupled to the power source 144 instead of the power source 120, and the power source 120 may be omitted.

In some embodiments that may be combined with other embodiments, the electrode 122 may be omitted. In some embodiments that may be combined with other embodiments, the electrode 122 (or another electrode in the support plate 112) is configured as a chucking electrode. In some embodiments that may be combined with other embodiments, the support plate 112 includes a heater, such as a resistive heating element. In some embodiments that may be combined with other embodiments, the substrate support 110 includes one or more coolant channels.

It is contemplated that the processing chamber 100 contains at least three lift pins 114. Each lift pin 114 is disposed through a corresponding hole 116 in the substrate support 110, and is moveable to lift the substrate 50 off the support surface 118 to facilitate transfer of the substrate 50 into and out of the processing chamber 100. In some embodiments that may be combined with other embodiments, each lift pin 114 is actuated by a corresponding lift pin system 170.

The support plate 112 is disposed on a support shaft 124 that extends through an aperture 106 in the floor 104 of the processing chamber 100. In some embodiments that may be combined with other embodiments, the support plate 112 is rotated by a drive mechanism (not shown) coupled to the support shaft 124 while the substrate 50 is undergoing processing in the processing chamber 100. Movement of the support shaft 124 (e.g., along the Z axis) raises or lowers the support plate 112 such that the support surface 118 is moved towards or away from the showerhead 140 (or the PVD target, if present).

The seal plate 113 is disposed on a support shaft 126 that extends through the aperture 106 in the floor 104 of the processing chamber 100. The support shaft 124 is disposed through the support shaft 126. Movement of the support shaft 126 (e.g., along the Z axis) raises or lowers the seal plate 113 such that the flexible element 190 of the seal plate 113 is moved towards or away from the liner assembly 180.

The support shaft 124 and the support shaft 126 are coupled to a base 160. The base 160 is coupled to an actuator assembly 150 that raises and lowers (e.g., along the Z axis) the base 160, and thus raises and lowers the support shaft 124 and the support shaft 126, and so raises and lowers the support plate 112 and the seal plate 113.

As illustrated, in some embodiments, the actuator assembly 150 includes a lift guide 152 and a carriage 158. The lift guide 152 includes a guide channel 154. A carriage 158 is movable along the lift guide 152. The carrier plate 156 is coupled to a carriage 158, which is movable along the guide channel 154. An actuator, such as a piston or a linear motor, moves the carriage 158 along the guide channel 154. Movement of the carriage 158 (e.g., along the Z axis) along the guide channel 154 moves the carrier plate 156 along the lift guide 152 between a lowered position and a raised position.

The support shaft 126 is coupled to the carrier plate 156. In some embodiments that may be combined with other embodiments, the support shaft 126 is coupled to the carrier plate 156 via a seal plate hub 166 (e.g., cooling hub) that is coupled to the support shaft 126. In an example, the seal plate hub 166 provides connections for the passage of a coolant to and from the seal plate 113. The seal plate hub 166 is coupled to an upper surface of the carrier plate 156, such as by bolts.

The carrier plate 156 includes an aperture through which the support shaft 124 extends. The support shaft 124 is coupled to a support plate hub 164. In an example, the support plate hub 164 provides connections for the passage of a coolant to and from the support plate 112. The support plate hub 164 is disposed below the seal plate hub 166 and below the carrier plate 156.

Movement of the carrier plate 156 along the lift guide 152 between a lowered position and a raised position moves the seal plate hub 166, the support shaft 126, the seal plate (113, FIGS. 1A, 1B), the support plate hub 164, the support shaft 124, and the support plate (112, FIGS. 1A, 1B) between lowered and raised positions.

In some embodiments that may be combined with other embodiments, a bellows 121 surrounds the support shaft 126 and extends between the seal plate hub 166 and the floor 104 of the processing chamber 100. In some embodiments that may be combined with other embodiments, a bellows 121 surrounds the support shaft 124 and extends between the support plate hub 164 and the carrier plate 156. The bellows 121 provide isolation of the environment within the processing chamber 100 from the ambient environment external to the processing chamber 100.

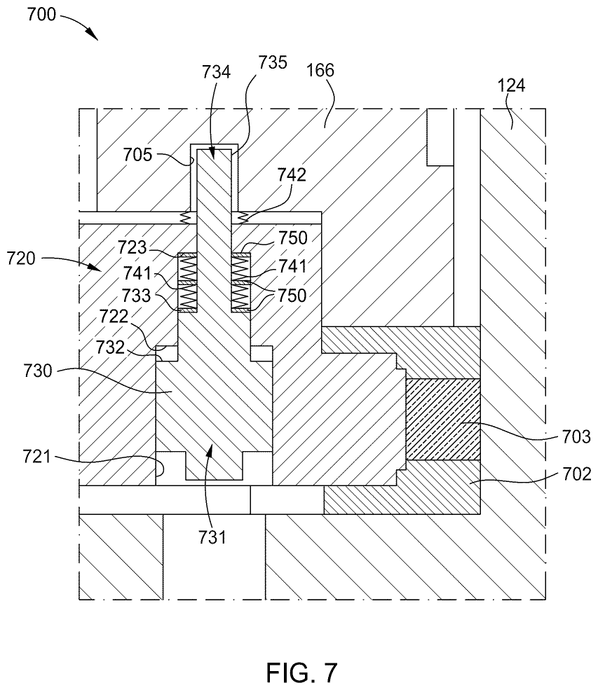

In some embodiments, one or more flexible assemblies 190A, such as the flexible assembly 710 shown in FIG. 7, may be used in addition to or in the place of the flexible element 190 to facilitate sealing off the first region 107 from the second region 108 despite a misalignment of the seal plate 113. The flexible assemblies 190A may be located at the base 160 and facilitate the independent movement of the seal plate hub 166, support shaft 126, and seal plate 113 relative to the support plate 112 and support shaft 124.

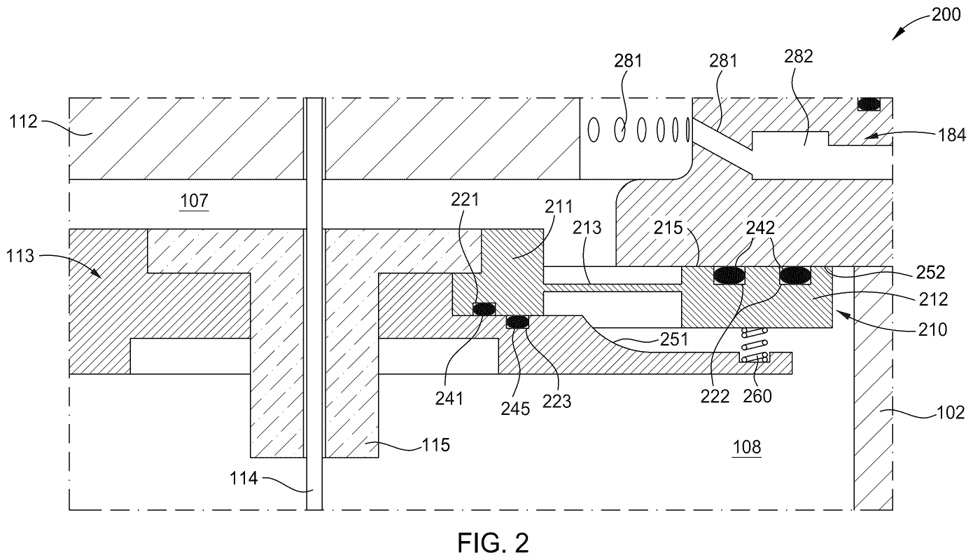

FIG. 2 illustrates a partial close-up cross-sectional view of a processing chamber 200. The processing chamber 200 has similar components and features as processing chamber 100 as indicated by the reference labels without reciting the description of these components and features for brevity. As shown, the processing chamber 200 includes the support plate 112, the seal plate 113, and the pumping ring 184, and the support plate 112 and the seal plate 113 are positioned in the processing position, which is similar to the processing chamber configuration illustrated in FIG. 1B. A lift pin 114 is disposed extending through the seal plate 113. In the processing chamber 200, the flexible element 190 is represented by flexible element 210. The flexible element 210 is configured to facilitate the sealing of the first region 107 from the second region 108 within the processing chamber 200 when the support plate 112 and the seal plate 113 are positioned in the processing position.

In some embodiments, the flexible element 210 is generally ring shaped. The cross-section of the flexible element 210 includes a first portion 211, a second portion 212, and an intermediate portion 213. The first portion 211 is annular, and is configured for attachment to the seal plate 113. The second portion 212 is annular, and is configured to move with the seal plate 113 to engage a chamber component, such as a component of the liner assembly 180, such as the pumping ring 184. The intermediate portion 213 is annular, and spans from the first portion 211 to the second portion 212. The intermediate portion 213 circumscribes the first portion 211. The second portion 212 circumscribes the intermediate portion 213.

The intermediate portion 213 can flex to allow adjustment of the position of the first portion 211 relative to the second portion 212, and vice versa, when the flexible element 210 is brought into contact with a chamber component, such as the pumping ring 184. However, the intermediate portion 213 is an impermeable barrier therethrough despite being flexible, which hinders fluid communication between the first region 107 and the second region 108 when the flexible element 210 is brought into contact with a chamber component. As illustrated, in some embodiments that may be combined with other embodiments, the intermediate portion 213 is generally planar, and is thinner (in the Z direction) than the first portion 211 and the second portion 212. For example, the intermediate portion 213 may be up to about 1 mm thick, such as between about 0.05 mm and about 1 mm, such as about 0.07 mm, about 0.1 mm, about 0.15 mm, about 0.2 mm, about 0.25 mm, about 0.3 mm, about 0.35 mm, about 0.4 mm, about 0.45 mm, about 0.5 mm, about 0.55 mm, about 0.6 mm, about 0.65 mm, about 0.7 mm, about 0.75 mm, about 0.8 mm, about 0.85 mm, about 0.9 mm, or about 0.95 mm. In some embodiments, the intermediate portion 213 has a thickness between about 0.1 mm to about 0.7 mm.

In some embodiments, the flexible element 210 is metallic, such as being made of aluminum, stainless steel, or Inconel. In some embodiments, the flexible element 210 is a monolithic structure. in some embodiments, the first portion 211, the second portion 212, and the intermediate portion 213 are made of the same material. In some embodiments, the intermediate portion 213 is made of a different material than the material of the first portion 211 and the second portion 212. In some examples, the material of the intermediate portion 213 is selected for flexibility and/or fatigue strength that is different than the material of the first portion 211 and the second portion 212.

The flexible element 210 is disposed on the seal plate 113, with the first portion 211 engaged with (e.g., seated on) a first interface surface 251 of the seal plate. The flexible element 210 may be raised and lowered relative to the pumping ring 184 along with the seal plate 113. A bracket 115, such as part of a lift pin guide or lift pin housing, may be engaged with the first portion 211 as shown in FIG. 2, such as holding the first portion 211 into engagement with the first interface surface 251. The first portion 211 may include one or more first seal grooves 221. A first seal element 241 (e.g., an o-ring) is disposed in each of the first seal grooves 221, and is engageable with the first interface surface 251. The first seal element(s) 241 seals the engagement of the first portion 211 with the first interface surface 251 to hinder fluid communication between the first region 107 and the second region 108. In some embodiments, the first interface surface 251 may include one or more seal grooves 223 to receive a seal element 245 (e.g., an o-ring) to seal against the first portion 211.

A first seal surface 215 of the second portion 212 of the flexible element 210 is engaged with a second interface surface 252 of the pumping ring 184 when the seal plate 113 is in the raised position to facilitate processing of the substrate 50 within the first region 107. The second portion 212 is biased toward engagement with the second interface surface 252 by one or more biasing members 260 disposed around the first interface surface 251. In some embodiments, the one or more biasing members 260 include three or more discrete compliant members (e.g., springs, such as helical springs, Belleville springs, or the like) that are disposed in a circular array that is positioned about a central axis (i.e., Z-axis) of the seal plate 113. The first seal surface 215 of the second portion 212 includes one or more, such as two, second seal grooves 222. A second seal element 242 (e.g., an o-ring or a lip seal) is disposed in each second seal groove 222 and seals against the second interface surface 252 when the seal plate 113 is in the raised position. In some embodiments that may be combined with other embodiments, the second portion 212 includes two second seal grooves 222, with a second seal element 242 disposed in one second seal groove 222, and a radio frequency (RF) gasket disposed in the other second seal groove 222.

The seal plate 113 may be misaligned relative to the pumping ring 184, such as being tilted due to tolerance differences, and the first seal surface 215 may be misaligned relative to the second interface surface 252. For example, the first seal surface 215 may be oriented in a first plane, and the second interface surface 252 may be oriented in a second plane that is oriented at an acute angle to the first plane. The flexible element 210 is configured to accommodate such misalignment. The flexibility of the intermediate portion 213 and the normal force applied by the one or more biasing members 260 allows the first seal surface 215 to become sufficiently aligned with the second interface surface 252 to facilitate a sealing engagement of the second seal elements 242 with the second interface surface 252 to hinder fluid communication between the first region 107 and the second region 108. In other words, the flexible element 210 facilitates sealing the first region 107 from the second region 108 despite a misalignment of the seal plate 113 with the pumping ring 184.

In some embodiments, the first seal surface 215 and the second interface surface 252 are both planar surfaces. In some embodiments, the first seal surface 215 is a non-planar surface, such as being a dome shaped surface.

In some embodiments, the seal between the first seal surface 215 and the second interface surface 252 is formed by metal to metal contact between the first seal surface 215 and the second interface surface 252. In other words, the second seal grooves 222 and second seal elements 242 may be omitted.

In some embodiments, the pressure within the second region 108 may be maintained at a pressure that exceeds the first region 107 to mitigate and/or prevent fluid leakage around the flexible element 210.

The vacuum pump 101 can evacuate gas from the first region 107 via the plurality of ports 281 formed in the pumping ring 184 that are connected by a plenum 282 to the exhaust port 103.

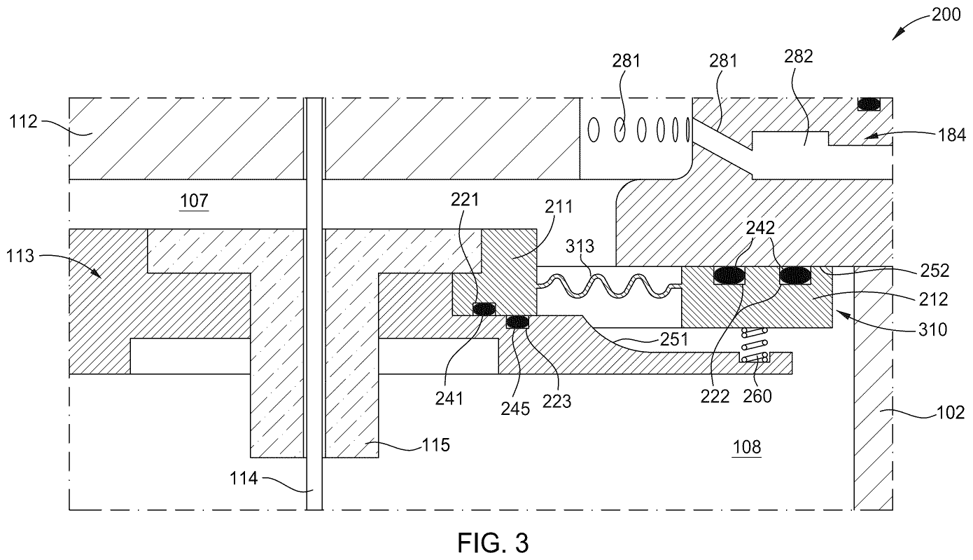

FIG. 3 illustrates a partial cross-sectional view of a processing chamber 300. The processing chamber 300 has similar components and features as processing chamber 200 as indicated by the reference labels without reciting the description of these components and features for brevity. In the processing chamber 300, the flexible element 190 is represented by flexible element 310. The flexible element 310 is similar to flexible element 210 (including the first portion 211 and the second portion 212), except that flexible element 310 has a corrugated intermediate section 313 that is substituted for the generally planar intermediate portion 213 of flexible element 210. The corrugated intermediate section 313 is annular, and spans from the first portion 211 to the second portion 212. The corrugated intermediate section 313 circumscribes the first portion 211. The second portion 212 circumscribes the corrugated intermediate section 313.

In some embodiments, the corrugated intermediate section 313 can include a plurality of concentric circular rings that are positioned about a central axis (i.e., Z-axis) of the seal plate 113. The flexible element 310 may be made of the same material as the flexible element 210. The corrugated intermediate section 313 is configured to control the radial and axial deformation of the corrugated intermediate section 313 when the flexible element 310 is brought into contact with a chamber component. The corrugated intermediate section 313 is also configured to distribute locally generated stress and strain within the corrugated intermediate section 313 when the flexible element 310 is brought into contact with a chamber component and is believed to improve the longevity of the flexible element 310 compared to the longevity of flexible element 210. The corrugated intermediate section 313 is annular, and spans from the first portion 211 to the second portion 212. The corrugated intermediate section 313 can flex to allow adjustment of the position of the first portion 211 relative to the second portion 212, and vice versa, when the flexible element 310 is brought into contact with a chamber component, such as the pumping ring 184. However, the corrugated intermediate section 313 is an impermeable barrier that hinders fluid communication between the first region 107 and the second region 108 when the flexible element 310 is brought into contact with a chamber component. As illustrated, in some embodiments that may be combined with other embodiments, the corrugated intermediate section 313 is thinner (in the Z direction) than the first portion 211 and the second portion 212. For example, the corrugated intermediate section 313 may be up to about 1 mm thick, such as between about 0.05 mm and about 1 mm, such as about 0.07 mm, about 0.1 mm, about 0.15 mm, about 0.2 mm, about 0.25 mm, about 0.3 mm, about 0.35 mm, about 0.4 mm, about 0.45 mm, about 0.5 mm, about 0.55 mm, about 0.6 mm, about 0.65 mm, about 0.7 mm, about 0.75 mm, about 0.8 mm, about 0.85 mm, about 0.9 mm, or about 0.95 mm. In some embodiments, the intermediate portion 213 has a thickness between about 0.1 mm to about 0.7 mm.

In some embodiments, the flexible element 310 is metallic, such as being made of aluminum, stainless steel, or Inconel. In some embodiments, the flexible element 310 is a monolithic structure. in some embodiments, the first portion 211, the second portion 212, and the corrugated intermediate section 313 are made of the same material. In some embodiments, the corrugated intermediate section 313 is made of a different material than the material of the first portion 211 and the second portion 212. In some examples, the material of the corrugated intermediate section 313 is selected for flexibility and/or fatigue strength that is different than the material of the first portion 211 and the second portion 212.

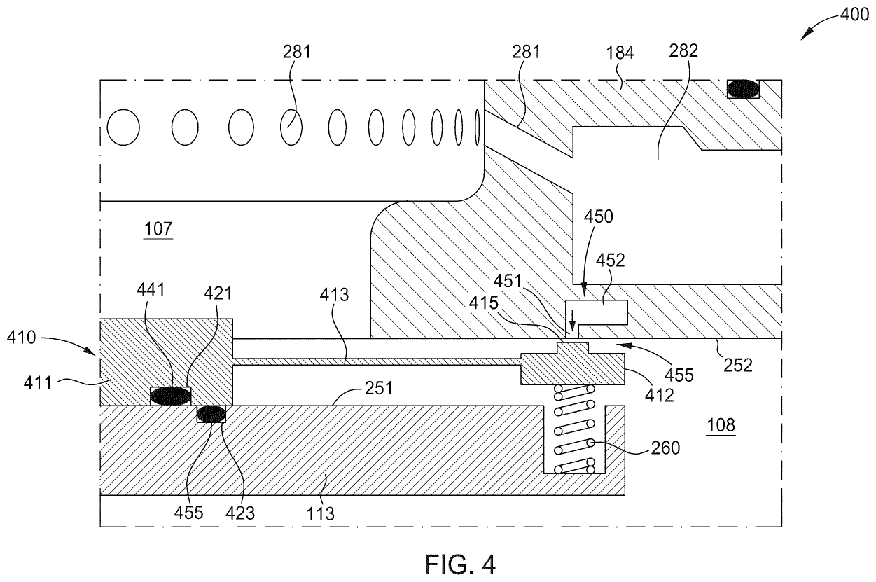

FIG. 4 illustrates a partial cross-sectional view of a processing chamber 400. The processing chamber 400 has similar components and features as processing chamber 200 as indicated by the reference labels without reciting the description of these components and features for brevity. In the processing chamber 400, the flexible element 190 is represented by flexible element 410. In some embodiments, the processing chamber 400 includes a gas bearing assembly 450 (e.g., a gas curtain assembly) to maintain a small gap 455 between a portion of the flexible element 410 and the second interface surface 252, as described below.

The flexible element 410 is generally circular and is disposed on the seal plate 113. The flexible element 410 may be made of the same material as the flexible element 210. The flexible element 410 includes a first portion 411, a second portion 412, and an intermediate portion 413. The first portion 411 is annular, and is configured for attachment to the seal plate 113. The second portion 412 is annular, and is configured to move with the seal plate 113 to engage a chamber component, such as a component of the liner assembly 180, such as the pumping ring 184. The intermediate portion 413 is annular, and spans from the first portion 411 to the second portion 412. The intermediate portion 413 circumscribes the first portion 411. The second portion 412 circumscribes the intermediate portion 413.

The intermediate portion 413 can flex to allow adjustment of the position of the first portion 411 relative to the second portion 412, and vice versa, when the flexible element 410 is brought into contact with (or into proximity with) a chamber component, such as the pumping ring 184. However, the intermediate portion 413 is an impermeable barrier that hinders fluid communication between the first region 107 and the second region 108 when the flexible element 410 is brought into contact with (or into proximity with) a chamber component. As illustrated, in some embodiments that may be combined with other embodiments, the intermediate portion 413 is generally planar, and is thinner (in the Z direction) than the first portion 411 and the second portion 412. For example, the intermediate portion 413 may be up to about 1 mm thick, such as between about 0.05 mm and about 1 mm, such as about 0.07 mm, about 0.1 mm, about 0.15 mm, about 0.2 mm, about 0.25 mm, about 0.3 mm, about 0.35 mm, about 0.4 mm, about 0.45 mm, about 0.5 mm, about 0.55 mm, about 0.6 mm, about 0.65 mm, about 0.7 mm, about 0.75 mm, about 0.8 mm, about 0.85 mm, about 0.9 mm, or about 0.95 mm. In some embodiments, the intermediate portion 213 has a thickness between about 0.1 mm to about 0.7 mm. In some embodiments that may be combined with other embodiments, the intermediate portion 413 is configured similarly to the corrugated intermediate section 313 of the flexible element 310.

In some embodiments, the flexible element 410 is metallic, such as being made of aluminum, stainless steel, or Inconel. In some embodiments, the flexible element 410 is a monolithic structure. in some embodiments, the first portion 411, the second portion 412, and the intermediate portion 413 are made of the same material. In some embodiments, the intermediate portion 413 is made of a different material than the material of the first portion 411 and the second portion 412. In some examples, the material of the intermediate portion 413 is selected for flexibility and/or fatigue strength that is different than the material of the first portion 411 and the second portion 412.

The flexible element 410 is disposed on the seal plate 113, with the first portion 411 engaged with (e.g., seated on) a first interface surface 251 of the seal plate 113. The flexible element 410 may be raised and lowered relative to the pumping ring 184 along with the seal plate 113. In some embodiments, the first portion 411 may include one or more first seal grooves 421. A first seal element 441 (e.g., an o-ring) is disposed in each of the first seal grooves 421 and engageable with the first interface surface 251. The first seal element(s) 441 seals the engagement of the first portion 411 with the first interface surface 251 to hinder fluid communication between the first region 107 and the second region 108. In some embodiments, the first interface surface 251 may include one or more seal grooves 423 to receive a seal element 445 (e.g., an o-ring) to seal against the first portion 411.

A first seal surface 415 of the second portion 412 of the flexible element 410 is engaged with (or is proximal to) a second interface surface 252 of the pumping ring 184 when the seal plate 113 is in the raised position to facilitate processing of the substrate 50 within the first region 107. The second portion 412 is shown as having an inverted “T” shape, with the first seal surface 415 being at the end of the stem of the “T.” The second portion 412 is biased toward the second interface surface 252 by the one or more biasing members 260 (e.g., in the form of springs, such as helical springs, Belleville springs, or the like) disposed around the first interface surface 251.

In some embodiments, such as embodiments in which the gas bearing assembly 450 is omitted or not used, the first seal surface 415 engages with and forms a metal-to-metal seal with the second interface surface 252. In embodiments in which the gas bearing assembly 450 is operated, a small gap 455 is formed to mitigate or prevent contact between the first seal surface 415 and the second interface surface 252 when the flexible element 410 is brought into proximity with a chamber component, such as pumping ring 184.

The seal plate 113 may be misaligned relative to the pumping ring 184, such as being tilted due to tolerance differences, and the first seal surface 415 may be misaligned relative to the second interface surface 252. For example, the first seal surface 415 may be oriented in a first plane, and the second interface surface 252 may be oriented in a second plane that is oriented at an acute angle to the first plane. The flexible element 410 is configured to accommodate such misalignment. The flexibility of the intermediate portion 413 and the normal force applied by the one or more biasing members 260 allows the first seal surface 415 to become sufficiently aligned with the second interface surface 252 to facilitate a sealing engagement of the first seal surface 415 with the second interface surface 252 to hinder fluid communication between the first region 107 and the second region 108. In other words, the flexible element 410 facilitates sealing the first region 107 from the second region 108 despite a misalignment of the seal plate 113 with the pumping ring 184.

The gas bearing assembly 450 includes a plurality of ports 451 in fluid communication with a plenum 452. A gas, such as a purge gas (e.g., an inert gas, such as nitrogen gas), is injected into the plenum 452 and flows out the ports 451 toward the first seal surface 415. The gas exiting the ports 451 helps maintain the gap 455 (with some contact occurring periodically in some embodiments) between the first seal surface 415 and the second interface surface 252. In some examples, the gap 455 maintained between the first seal surface 415 and the second interface surface 252 is from about 0.01 mm to about 0.2 mm. Gas flow from the ports 451 into the gap 455 mitigates or prevents contact between the second interface surface 252 and the flexible element 410, and hinders particle generation at the second portion 412. Also, the gas flow helps create a fluid barrier to hinder fluid communication between the first region 107 and the second region 108. The formed fluid barrier may vary in thickness around the flexible element 410, such as due to a misalignment between the seal plate 113 and the pumping ring 184 that is partially accommodated by the flexibility of the intermediate portion 413 and the normal force applied by the one or more biasing members 260. However, the fluid barrier still facilitates the hindering of fluid communication between the between the first region 107 and the second region 108 despite such misalignment. Additionally, the fluid barrier is advantageous in high temperature (e.g., over 200 degrees Celsius) processes within the first region 107, since elastomeric seals at the interface between the second interface surface 252 and flexible element 410 can be omitted.

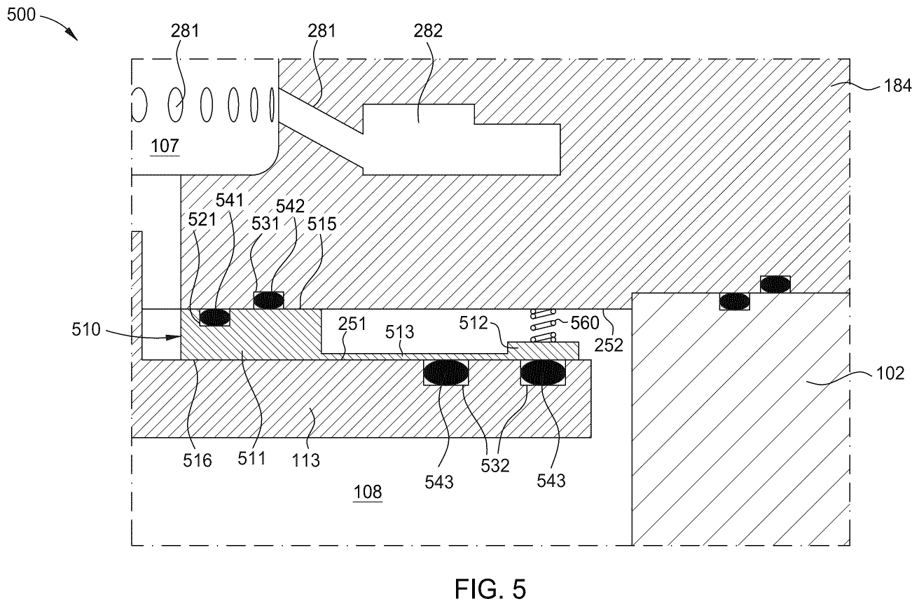

FIG. 5 illustrates a partial cross-sectional view of a processing chamber 500. The processing chamber 500 has similar components and features as processing chamber 200 as indicated by the reference labels without reciting the description of these components and features for brevity. In the processing chamber 500, the flexible element 190 is represented by flexible element 510. The flexible element 510 facilitates sealing the first region 107 from the second region 108 within the processing chamber 500.

The flexible element 510 is generally ring shaped. The cross-section of the flexible element 510 includes a first portion 511, a second portion 512, and an intermediate portion 513. The first portion 511 is annular, and is configured for attachment to a chamber component, such as a component of the liner assembly 180, such as the pumping ring 184. The second portion 512 is annular, and is configured to engage the seal plate 113. The intermediate portion 513 is annular, and spans from the first portion 511 to the second portion 512. The intermediate portion 513 circumscribes the first portion 511. The second portion 512 circumscribes the intermediate portion 513.

The intermediate portion 513 can flex to allow adjustment of the position of the first portion 511 relative to the second portion 512, and vice versa, when the flexible element 510 is brought into contact with the seal plate 113. However, the intermediate portion 513 is an impermeable barrier that hinders fluid communication between the first region 107 and the second region 108 when the flexible element 510 is brought into contact with the seal plate 113. As illustrated, in some embodiments that may be combined with other embodiments, the intermediate portion 513 is generally planar, and is thinner (in the Z direction) than the first portion 511 and the second portion 512. For example, the intermediate portion 513 may be up to about 1 mm thick, such as between about 0.05 mm and about 1 mm, such as about 0.07 mm, about 0.1 mm, about 0.15 mm, about 0.2 mm, about 0.25 mm, about 0.3 mm, about 0.35 mm, about 0.4 mm, about 0.45 mm, about 0.5 mm, about 0.55 mm, about 0.6 mm, about 0.65 mm, about 0.7 mm, about 0.75 mm, about 0.8 mm, about 0.85 mm, about 0.9 mm, or about 0.95 mm. In some embodiments, the intermediate portion 213 has a thickness between about 0.1 mm to about 0.7 mm.

In some embodiments, the flexible element 510 is metallic, such as being made of aluminum, stainless steel, or Inconel. In some embodiments, the flexible element 510 is a monolithic structure. in some embodiments, the first portion 511, the second portion 512, and the intermediate portion 513 are made of the same material. In some embodiments, the intermediate portion 513 is made of a different material than the material of the first portion 511 and the second portion 512. In some examples, the material of the intermediate portion 513 is selected for flexibility and/or fatigue strength that is different than the material of the first portion 511 and the second portion 512.

In some embodiments, the flexible element 510 is attached (e.g., bolted) to the pumping ring 184 such that the first interface surface 251 of the seal plate 113 contacts the flexible element 510 when moved to the raised position depicted in FIG. 1B, and is disengaged from the flexible element 510 when in the lower position depicted in FIG. 1A. The flexible element 510 may be attached by one or more fasteners, adhesive, or other suitable attachment mechanism. A first seal surface 515 of the first portion 511 is engaged with the second interface surface 252. The first seal surface 515 of the first portion 511 may include one or more first seal grooves 521. A first seal element 541 (e.g., an o-ring) is disposed in each of the first seal grooves 521 and engageable with the second interface surface 252. The first seal element(s) 541 seals the engagement of the first portion 511 with the second interface surface 252 to hinder fluid communication between the first region 107 and the second region 108. In some embodiments, the second interface surface 252 may include one or more seal grooves 531 to receive a seal element 542 (e.g., an o-ring) to seal against the first portion 511.

The first seal surface 515 is located on a first side (e.g., upper side) of the flexible element 510. A second seal surface 516 is located on a second side (e.g., lower side) of the flexible element 510 and extends along and is defined by a surface of the first portion 511, second portion 512, and intermediate portion 513. Thus, the intermediate portion 513 may be in contact with the seal plate 113. The second seal surface 516 is engaged with a first interface surface 251 when the seal plate 113 is in the raised position to facilitate processing of the substrate 50 within the first region 107. The second portion 512 is biased toward engagement with the first interface surface 251 by one or more biasing members 560 (e.g., springs, such as helical springs, Belleville springs, or the like) disposed around the second interface surface 252. As shown, the one or more biasing members 560 are disposed between, and engaged with, the second interface surface 252 and the second portion 512.

The second seal surface 516 facilitates forming a seal between the flexible element 510 and the seal plate 113. In some embodiments, the first interface surface 251 may include one or more seal grooves 532 (two are illustrated) that each receive a seal member 543 (e.g., an o-ring or a lip seal). In some embodiments that may be combined with other embodiments, and as shown in FIG. 5, one seal member 543 is engaged with the second portion 512 while another seal member 543 is engaged with the intermediate portion 513. In some embodiments that may be combined with other embodiments, a seal member 543 is disposed in one of the one or more seal grooves 532, and an RF gasket is disposed in another one of the one or more seal grooves 532. In some embodiments that may be combined with other embodiments, a further seal member 543 is disposed in another seal groove 532 in the first interface surface 251 to engage the first portion 511. In some embodiments, the seal members 543 and seal grooves 532 are omitted, and the seal is formed by metal to metal contact between the first interface surface 251 and the second seal surface 516.

The seal plate 113 may be misaligned relative to the pumping ring 184, such as being tilted due to tolerance differences, and the first interface surface 251 may be misaligned relative to the second seal surface 516. For example, the first interface surface 251 may be oriented in a first plane, and the second seal surface 516 at the second portion 512 may be oriented in a second plane that is oriented at an acute angle to the first plane. The flexible element 510 is configured to accommodate such misalignment. The flexibility of the intermediate portion 513 and the normal force applied by the one or more biasing members 560 allows the second seal surface 516 to become sufficiently aligned with the first interface surface 251 to facilitate a tight sealing engagement to hinder fluid communication between the first region 107 and the second region 108. In other words, the flexible element 510 facilitates sealing the first region 107 from the second region 108 despite a misalignment of the seal plate 113 with the pumping ring 184.

In some embodiments, the first seal surface 515 and the second interface surface 252 are both planar surfaces. In some embodiments, the first seal surface 515 is a non-planar surface, such as being a dome shaped surface. In some embodiments, and as shown in FIG. 5, the second seal surface 516 is a planar surface.

In some embodiments, the seal between the first seal surface 515 and the second interface surface 252 is formed by metal to metal contact between the first seal surface 515 and the second interface surface 252. In other words, the first seal grooves 521 and the first seal elements 541 may be omitted.

In some embodiments, the pressure within the second region 108 may be maintained at a pressure that exceeds the first region 107 to mitigate and/or prevent fluid leakage around the flexible element 510 from the first region 107 to the second region 108.

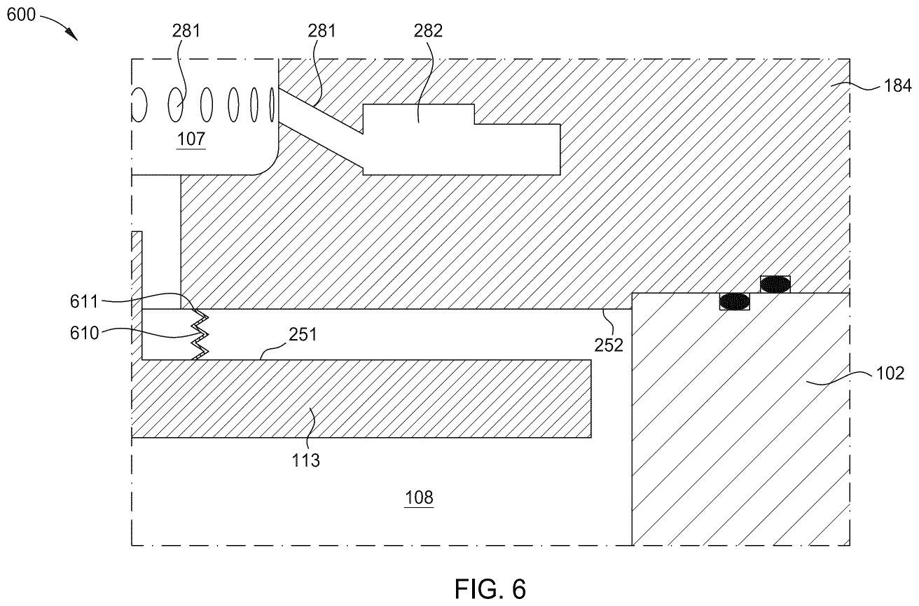

FIG. 6 illustrates a partial cross-section of processing chamber 600. The processing chamber 600 has similar components and features as processing chamber 200 as indicated by the reference signs without reciting the description of these components and features for brevity. In the processing chamber 600, the flexible element 190 is represented by flexible element 610. Flexible element 610 is a bellows element that encircles a portion of the seal plate 113. The flexible element 610 may be attached at one end to the first interface surface 251, such as being welded. One or more seal elements may hinder fluid communication around the interface between the flexible element 610 and the seal plate 113. The free end 611 (e.g., other end) of the flexible element 610 is separable from and selectively engageable with the second interface surface 252 when the seal plate 113 is moved to the raised position. The flexible element 610 is compressible between the seal plate 113 and pumping ring 184 to form a seal even though the seal plate 113 may be misaligned with respect to the pumping ring 184. The free end 611 may include a seal element, such as an o-ring or a lip seal, that can engage with the second interface surface 252.

FIG. 7 illustrates a partial cross-section at a base 700 of a processing chamber, such as any of processing chambers 100, 200, 300, 400, 500, or 600. Each of the flexible assemblies 190A identified in FIGS. 1A and 1B is represented by a flexible assembly 710, one of which is illustrated in FIG. 7. The flexible assembly 710 is placed similarly to where flexible assembly 190A is shown in FIGS. 1A and 1B. As shown, the flexible assembly 710 is coupled to an end of the seal plate hub 166 that is connected to the seal plate 113. The seal plate hub 166 is around the support shaft 124 that is connected to the support plate 112. A plurality of flexible assemblies 710 are distributed around the support shaft 124 to facilitate independent movement of the seal plate hub 166 relative to the support shaft 124. In other words, the flexible assemblies 710 facilitate independent movement of the seal plate 113 relative to the support plate 112, which allows the seal plate 113 sufficient play to correct a misalignment with another component of the processing chamber that the seal plate 113 will seal against when in the raised position.

In some embodiments, the flexible assemblies 710 are disposed in a body 702 that is disposed around the support shaft 124 and is sandwiched between the seal plate hub 166 and the support shaft 124. In some embodiments, one or more seals 703 (such as one or more o-rings, lip seals, labyrinth seals, or chevron seals) may be used to seal the interface between the body 702 and the support shaft 124.

Each flexible assembly 710 includes a housing 720 and a rod 730 (e.g., retainer bolt). The housing 720 may be disposed in the body 702 and may be engaged with the seal plate hub 166 and/or the support shaft 124. The housing 720 includes a bore 721 that receives the rod 730. In some embodiments, the bore 721 and rod 730 have varying diameters.

The rod 730 has a first portion 731 (e.g., head) with a first shoulder 732 that is engageable with a first shoulder 722 of the housing 720 that partially defines the bore 721. The rod 730 has a second portion 734 that extends out of the housing 720 and includes an end 735 that extends into a corresponding bore 705 of the seal plate hub 166. The second portion 734 has a second shoulder 733. The housing 720 also has a second shoulder 723 that partially defines the bore 721.

The flexible assembly 710 includes one or more first biasing elements 741, such as disc springs, disposed around the second portion 734 between the opposing shoulders 723, 733. In some embodiments, washers 750 may be disposed around the second portion 734 of the rod 730. For example, and as shown in FIG. 7, a washer 750 may be between two sets of first biasing elements 741. Washers 750 may also separate the first biasing elements 741 from contact with the housing 720 and/or rod 730 as shown in FIG. 7.

The flexible assembly 710 includes one or more second biasing elements 742, such as disc springs, disposed around the second portion 734 and engaged with the seal plate hub 166 and the housing 720.

In some embodiments, the first portion 731 of the rod 730 is threaded to the housing 720 and tightened against the one or more first biasing elements 741. The end 735 is not fixed to the seal plate hub 166. Thus, the seal plate hub 166 can move (e.g., wobble) relative to the end 735 of the rod 730. The one or more second biasing elements 742 facilitate the movement of the seal plate hub 166 relative to the support shaft 124 and also provide a normal force that helps the seal plate 113 press against the component that it is sealing against when in the raised position.

In some embodiments, the first portion 731 is slidable within the bore 721 of the housing 720. The end 735 is threaded to or otherwise affixed to the seal plate hub 166. Thus, the rod 730 can move with the seal plate hub 166. The one or more first biasing elements 741 and the one or more second biasing elements 742 facilitate the movement of the seal plate hub 166 relative to the support shaft 124 and also provide a normal force that helps the seal plate 113 press against the component that it is sealing against when in the raised position.

It is contemplated that any one or more elements or features of any one disclosed embodiment may be beneficially incorporated in any one or more other non-mutually exclusive embodiments. While the foregoing is directed to embodiments of the present disclosure, other and further embodiments of the disclosure may be devised without departing from the basic scope thereof, and the scope thereof is determined by the claims that follow.

What is claimed is:

1. An assembly for use in a substrate processing chamber, the assembly comprising:
a flexible element comprising:
a first portion that is annular;
a second portion circumscribing the first portion; and
an intermediate portion spanning between the first portion and the second portion;
wherein the intermediate portion is impermeable, and is configured to flex to allow adjustment of a position of the first portion relative to the second portion.

2. The assembly of claim 1, wherein the intermediate portion has a thickness less than a thickness of the first portion and less than a thickness of the second portion.

3. The assembly of claim 1, wherein the intermediate portion has a thickness up to about 1 mm.

4. The assembly of claim 1, wherein the intermediate portion has a planar form or a corrugated form.

5. The assembly of claim 1, further comprising a seal surface on the second portion.

6. The assembly of claim 1, further comprising a biasing member coupled to the second portion.

7. The assembly of claim 1, wherein the flexible element is a monolithic structure of a single material.

8. A processing chamber comprising:
a chamber body;
a seal plate disposed in the chamber body, and including a first interface surface;
a second interface surface disposed in the chamber body;
a flexible element including:
a first portion engaged with the first interface surface;
a second portion facing the second interface surface; and
an intermediate portion spanning between the first portion and the second portion;
wherein the intermediate portion is impermeable, and is configured to flex to allow adjustment of a position of the first portion relative to the second portion.

9. The processing chamber of claim 8, further comprising a plurality of ports formed in the second interface surface, and configured to direct a gas at the second portion.

10. The processing chamber of claim 9, further comprising a seal surface on the second portion facing the plurality of ports.

11. The processing chamber of claim 8, further comprising a plurality of biasing members disposed between and engaged with the first interface surface and the second portion.

12. The processing chamber of claim 8, wherein the intermediate portion has a thickness less than a thickness of the first portion and less than a thickness of the second portion.

13. The processing chamber of claim 8, wherein the intermediate portion has a thickness up to about 1 mm.

14. The processing chamber of claim 8, wherein the intermediate portion has a planar form or a corrugated form.

15. The processing chamber of claim 8, wherein the flexible element is a monolithic structure of a single material.

16. A processing chamber comprising:
a chamber body;
a seal plate disposed in the chamber body, and including a first interface surface;
a second interface surface disposed in the chamber body;
a flexible element including:
a first portion engaged with the second interface surface;
a second portion facing the first interface surface; and
an intermediate portion spanning between the first portion and the second portion;
wherein the intermediate portion is impermeable, and is configured to flex to allow adjustment of a position of the first portion relative to the second portion.

17. The processing chamber of claim 16, further comprising a seal surface on the second portion facing the first interface surface.

18. The processing chamber of claim 16, further comprising a plurality of biasing members disposed between and engaged with the second interface surface and the second portion.

19. The processing chamber of claim 16, wherein the intermediate portion has a thickness less than a thickness of the first portion and less than a thickness of the second portion.

20. The processing chamber of claim 16, wherein the intermediate portion has a thickness up to about 1 mm.
